(19) United States
(12) Patent Application Publication
(10) Pub. No.: US 2014/0362497 A1
(43) Pub. Date: Dec. 11, 2014

(54) POWER SUPPLY ASSEMBLY

(71) Applicants: HON HAI PRECISION INDUSTRY CO., LTD., New Taipei (TW); HONG FU JIN PRECISION INDUSTRY (WuHan) CO., LTD., Wuhan (CN)

(72) Inventors: GUANG-LEI ZHANG, Wuhan (CN); FA-YANG LI, Wuhan (CN); XIAO-ZHONG JING, Wuhan (CN); YI-TING HSIEH, New Taipei (TW); GUANG-YAO LEE, New Taipei (TW)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 13/928,217

(22) Filed: Jun. 26, 2013

(30) Foreign Application Priority Data
Jun. 10, 2013 (CN) 2013102312662

(51) Int. Cl. H05K 7/14

(52) U.S. Cl. CPC H05K 7/14
USPC 361/622

(57) ABSTRACT

A power supply assembly includes a bracket defining an opening, a plurality of power supply units detachably installed in the bracket through the opening, and a plurality of shunt-wound connectors mounted in the bracket opposite to the opening. Each power supply unit includes a plug. The plugs of the power supply units are detachably and electrically coupled to the connectors.

### BACKGROUND

1. Technical Field

The present disclosure relates to a power supply assembly.

2. Description of Related Art

A power supply unit installed in an electronic device supplies power to the electronic device. To replace the power supply unit, the electronic device needs to be powered off completely. Therefore, it is desirable to provide a power supply assembly that can overcome the above-mentioned problems.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of one embodiment of a power supply assembly.

FIG. 2 is an inverted view of FIG. 1.

FIG. 3 is an assembled, isometric view of FIG. 1.

FIG. 4 is an isometric view showing the processes of using the power supply assembly of FIG. 3 in one state.

FIG. 5 is an isometric view showing the processes of using the power supply assembly of FIG. 3 in another state.

FIG. 6 is an isometric view showing the processes of using the power supply assembly of FIG. 3 in yet another state.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

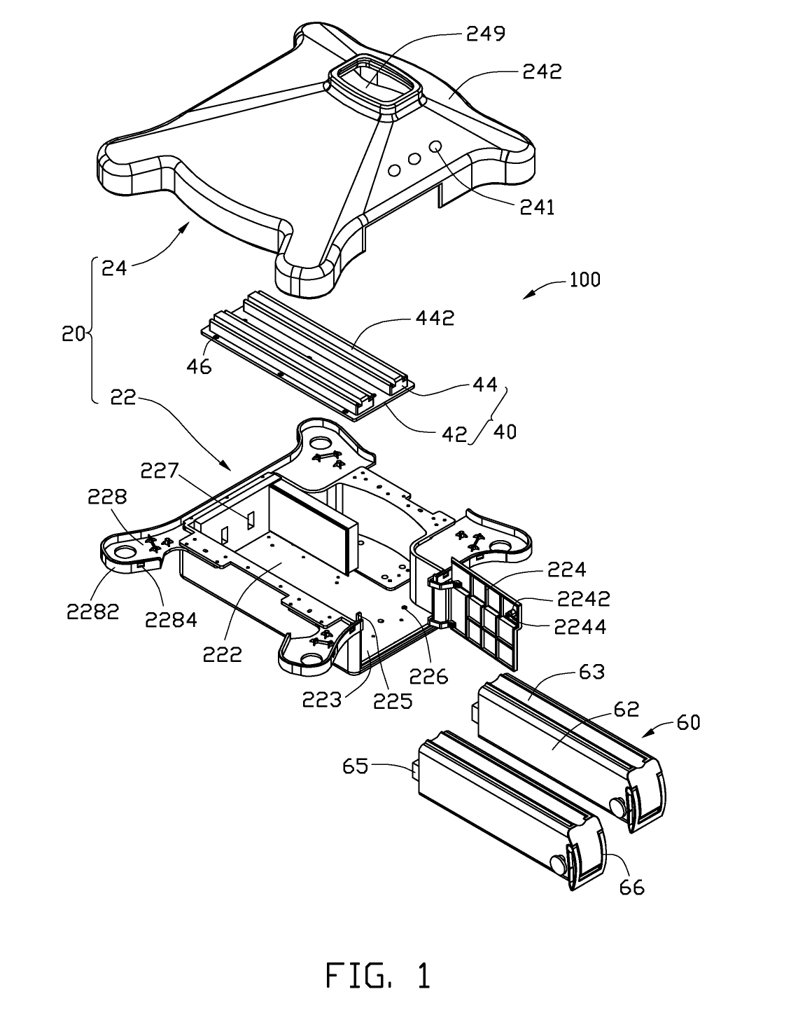

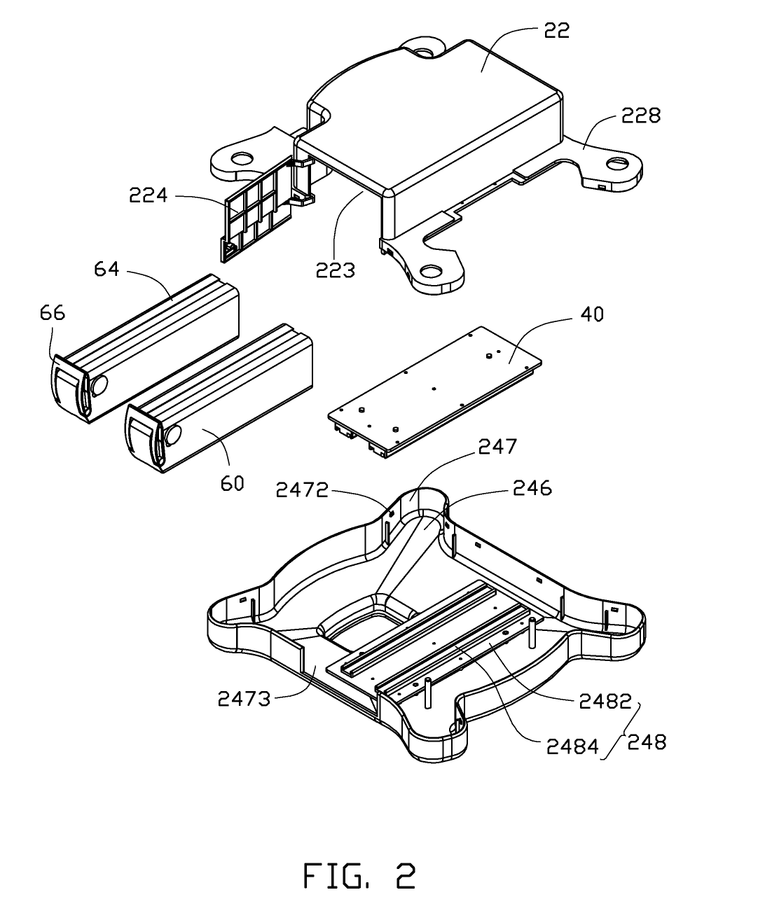

FIGS. 1 and 2 show one embodiment of a power supply assembly 100. The power supply assembly 100 includes a bracket 20, a supporting member 40, and two power supply units 60. The bracket 20 includes a chassis 22 and a cover 24.

The chassis 22 can be substantially rectangular and define a receiving space 222 extending through an end of the chassis 22 to form an opening 223 in the end of the chassis 22. A door 224 can be connected rotatably to the chassis 22 at side of the opening 223 to cover or uncover the opening 223. A pole 225 can extend up from the chassis 22, adjacent to an opposite side of the opening 223. A bottom wall of the receiving space 222 includes a plurality of mounting holes 226. Two spaced and shunt-wound connectors 227 can be mounted to a sidewall bounding the receiving space 222 opposite to the opening 225. A latching member 2242 can be rotatably installed to a distal end of the door 224 opposite to a rotation junction between the door 224 and the chassis 22. The latching member 2242 includes a latching piece 2244 detachably latched to the pole 225. Four tabs 228 extend out from four corners of a top of the chassis 22. A flange 2282 extends substantially perpendicularly up from sides of each tab 228. The flange 2282 includes a plurality of latching holes 2284.

The cover 24 includes a substantially rectangular top plate 242, four tabs 246 extending out from four corners of the top plate 242, a flange 247 extending substantially perpendicularly down from sides of the top plate 242 and the tabs 246, and a positioning member 248 mounted to a bottom surface of the top plate 242. A plurality of resilient latching blocks 2472 protrudes in from the flange 247, adjacent to the tabs 246. The positioning member 248 includes a rectangular mounting plate 2482 mounted to the bottom surface of the top plate 242, and two substantially parallel and spaced guiding rails 2484 protruding down from opposite sides of the mounting plate 2482. The flange 247 defines a cutout 2473 aligning with an end of the mounting plate 2482. A plurality of indication lights 241 can be installed on an outer surface of the top plate 242 to show the energy level of the power supply units 60. The top plate 242 includes a through hole 249.

The supporting member 40 includes a rectangular supporting plate 42 and two substantially parallel and spaced protruding bars 44 protruding substantially perpendicularly up from two opposite sides of the supporting plate 42. A sliding rail 442 protrudes up from a top of each protruding bar 44, along the lengthwise direction of the supporting plate 42. The supporting plate 42 includes a plurality of through holes 46.

Each of the power supply unit 60 includes a rectangular main body 62. A top of the main body 62 defines a guiding slot 63 along a lengthwise direction of the main body 62. A bottom of the main body 62 includes a slide slot 64 along the lengthwise direction of the main body 62. A plug 65 can be mounted to a rear end of the main body 62, and electrically coupled to the main body 62. An operation member 66 can be installed to a front end of the main body 62 opposite to the plug 65.

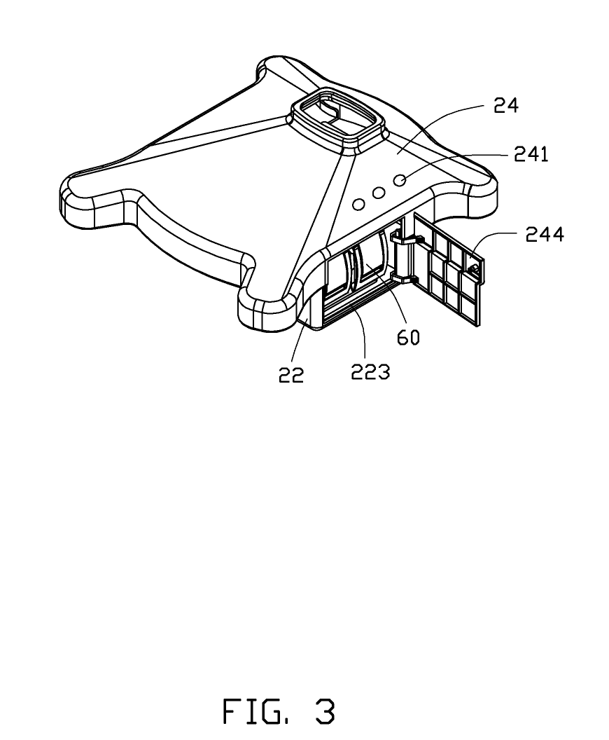

FIG. 3 shows that in assembly of the power supply assembly 100, the supporting member 40 can be received in the receiving space 222 of the chassis 22. The supporting plate 42 is supported on the bottom wall of the receiving space 222. An end of the supporting member 40 aligns with the opening 223. A plurality of screws extends through the through holes 46 of the supporting plate 42, and can be screwed in the mounting holes 226. An end of a cable (not shown) can be electrically coupled to the connectors 227, and an opposite end of the cable extends through the through hole 249 can be electrically coupled to an electronic device (not shown). The cover 24 is covered on the chassis 22. The guiding rails 2484 align with the sliding rails 442, and the cutout 2473 aligns with the opening 223 of the chassis 22. The cover 24 is pressed toward the chassis 22. The latching blocks 2472 slidably abut against an outer surface of the flanges 2282 of the chassis 22, deforming the latching blocks 2472, until the latching blocks 2472 align with the corresponding latching holes 2284. The latching blocks 2472 can be restored to latch in the latching holes 2284. Thereby, the cover 24 can be mounted on the chassis 22. The rear ends of the power supply units 60 can be inserted into the receiving space 222 through the opening 223 and the cutout 2473. The sliding rails 442 and the guiding rails 2484 can be slidably received in the sliding slots 64 and the guiding slots 63, respectively, until the plugs 65 coupled with the connectors 227. The door 224 can be rotated to cover the opening 223 and the cutout 2473. The latching member 2242 can be operated to allow the latching piece 2244 to latch with the pole 225.

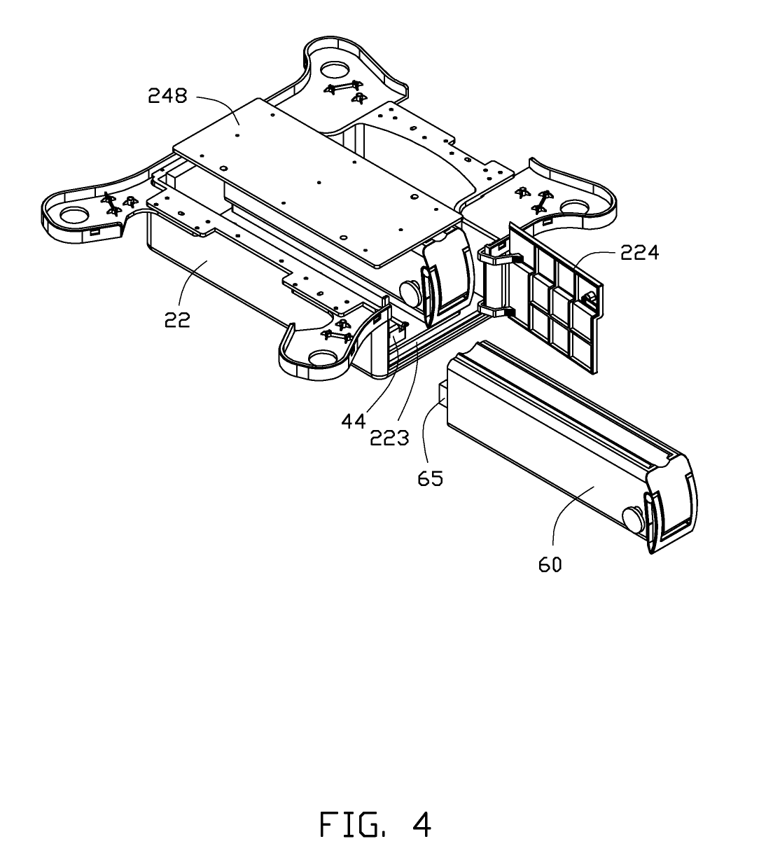

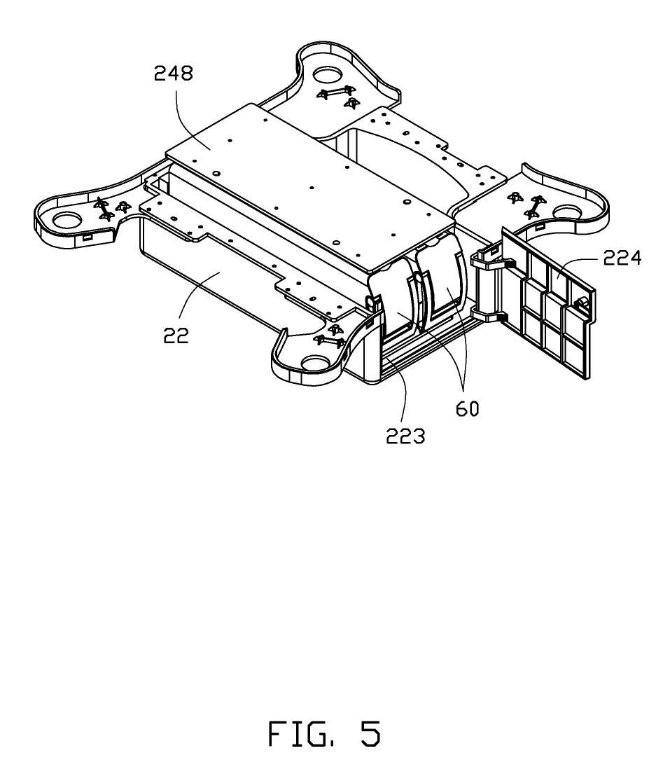

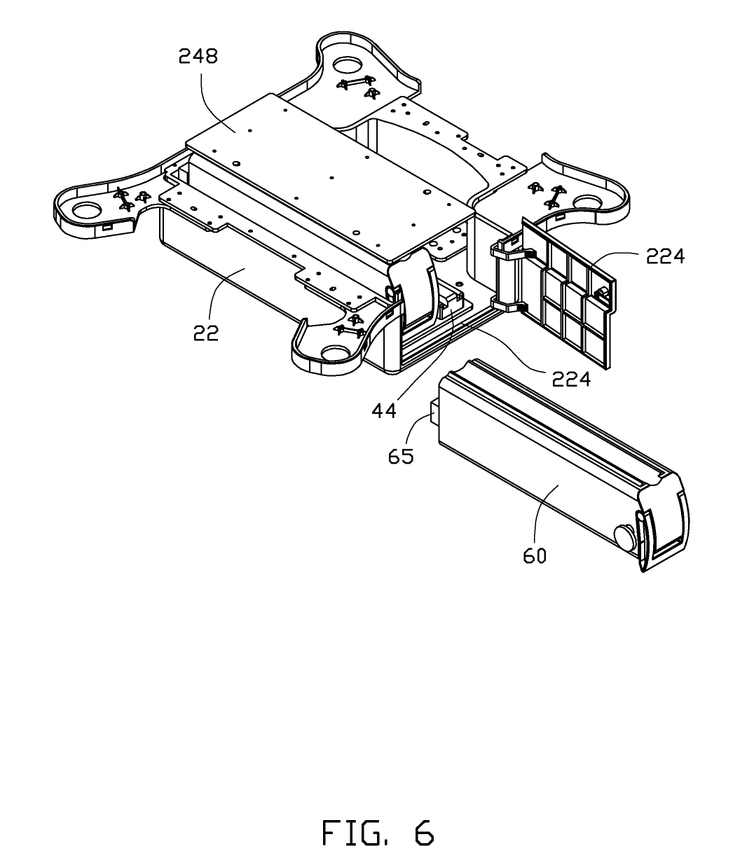

FIGS. 4-6 show that one of the power supply units 60 can be replaced with a new power supply unit 60 without powering down the electronic device. Each of the power supply units 60 can supply power to the electronic device. When the indication lights 241 show that one of the power supply units 60 is low or out of energy, the door 224 can be opened and another power supply unit 60 can be inserted in the receiving space 222, with the plug 65 connected to the corresponding connector 227. The power supply units 60 can be pulled out of the chassis 22 with the operation member 66 operated.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A power supply assembly, comprising:
a bracket defining an opening;
a plurality of power supply units detachably installed in the bracket through the opening, each power supply unit comprising a plug; and
a plurality of shunt-wound connectors mounted in the bracket, opposite to the opening, wherein the plugs of the power supply units are detachably and electrically coupled to the connectors.

2. The power supply assembly of claim 1, further comprising a supporting member, the bracket defines a receiving space communicating with the opening, the supporting member is received in the receiving space and comprises two substantially parallel sliding rails, the sliding rails extend along a sliding direction of the power supply units, and a bottom surface of each power supply unit defines a slide slot for slidably receiving the corresponding sliding rail, thereby slidably receiving the power supply units in the receiving space.

3. The power supply assembly of claim 2, wherein the supporting member further comprises a supporting plate mounted on a bottom of the receiving space, and two substantially parallel protruding bars protruding up from two sides of the supporting plate opposite to the opening, each protruding bar extends along the sliding direction of the power supply unit, and the sliding rails protrude up from tops of the protruding bars.

4. The power supply assembly of claim 2, wherein the bracket comprises a chassis and a cover covered on the chassis, the receiving space and the opening are defined in the chassis, the cover comprises a top plate and a flange extending down from sides of the top plate, and the flange defines a cutout aligning with the opening of the chassis.

5. The power supply assembly of claim 4, wherein the cover further comprises a positioning member, the positioning member comprises a mounting plate mounted to a bottom of the top plate and two substantially parallel guiding rails protruding down from the mounting plate, a top of each power supply unit defines a guiding slot for slidably receiving the corresponding guiding rail, and the power supply units are sandwiched between the sliding rails of the chassis and the guiding rails of the cover.

6. The power supply assembly of claim 4, wherein the chassis comprises a door rotatably connected to the chassis adjacent to a side of the opening, the chassis further comprises a pole extending up from the chassis adjacent to an opposite side of the opening, the door comprises a latching member installed to a distal end of the revolution door, and the latching member is detachably latched to the pole.

7. The power supply assembly of claim 1, wherein the bracket comprises a plurality of indication lights showing quantity of power of the power supply units.
